(19) United States
(12) Patent Application Publication
(10) Pub. No.: US 2026/0264551 A1
(43) Pub. Date: Sep. 10, 2026

(54) CURB OR PAVING STONE CHARGING DEVICE FOR CHARGING AN ENERGY STORE OF AN ELECTRICALLY DRIVEN VEHICLE

(71) Applicant: PIERBURG GMBH, NEUSS (DE)

(72) Inventors: FELIX STRACKE, NEUSS (DE); AXEL HEMSING, NEUSS (DE); JENS HOFFMANN, NEUSS (DE); ANDREAS BRETZ, NEUSS (DE)

(73) Assignee: PIERBURG GMBH, NEUSS (DE)

(21) Appl. No.: 18/873,745

(22) PCT Filed: May 6, 2023
(86) PCT No.: PCT/EP2023/062073

§ 371 Date: Dec. 11, 2024

(30) Foreign Application Priority Data
Jun. 29, 2022 (WO) PCT/EP2022/067866
Aug. 9, 2022 (WO) PCT/EP2022/072334

(51) Int. Cl. B60L 53/302; B60L 53/18; B60L 53/30; H05K 7/20

(52) U.S. Cl. CPC B60L 53/302; B60L 53/18; B60L 53/32; H05K 7/20336; H05K 7/20445

(57) ABSTRACT

A charging device for a curbstone, a paving stone, or a curbstone for charging a battery of an electric car. The charging device includes a main body, a protective cover, an interface unit, a power supply unit and an electronic component which generates heat. The main body has an accommodating space, and an outer wall having an inner wall surface which faces an outer wall surface. The protection cover closes the accommodating space. The power supply cable projects into the accommodating space. The electronic component is arranged in the accommodating space and connects the interface unit to the power supply cable. The electronic component either directly abuts against the inner wall surface of the outer wall to conduct heat, or a heat-conducting body is arranged to extend at least from the electronic component to the inner wall surface. The outer wall surface rests against surrounding soil or against a foundation.

### CROSS REFERENCE TO PRIOR APPLICATIONS

This application is a U.S. National Phase application under 35 U.S.C. § 371 of International Application No. PCT/EP 2023/062073, filed on May 6, 2023 and which claims benefit to International Patent Application No. PCT/EP2022/067866, filed on Jun. 29, 2022, and to International Patent Application No. PCT/EP2022/072334, filed on Aug. 9, 2022. The International Application was published in German on Jan. 4, 2024 as WO 2024/002565 A1 under PCT Article 21(2).

### FIELD

The present invention relates to a curbstone, a paving stone or a curbstone charging device for charging an energy accumulator of an electrically driven vehicle, with a main body comprising an interior accommodating space closed via a protection cover, an interface unit, a power supply cable that extends into the accommodating space in the main body, and heat-generating electronic components that are arranged in the accommodating space of the main body and via which the interface unit is connected to the power supply cable.

### BACKGROUND

These curbstone, paving stone or curbstone charging devices are charging stations integrated into the curbstone, paving stone or curbstone, to which vehicles can be connected via an electrical connection in order to charge their energy accumulators or batteries. This in particular applies to purely electrically driven vehicles but also to hybrid vehicles. Rechargeable vehicles can be both passenger cars and trucks, as well as motorcycles or electric bicycles.

Due to the new legislation, the population's increasing interest in climate protection, and the improved economic efficiency of electrified vehicles, it is expected that the share of electrically driven vehicles will increase dramatically, especially in urban regions, meaning that the available charging infrastructure must be greatly expanded. This means that some existing parking spaces will have to be equipped with appropriate charging options to provide individual mobility in the future.

Known concepts provide for the use of streetlamps in addition to charging stations to be installed or wall boxes at house walls. Additional space is needed for all these concepts and pedestrians are disturbed by the charging cables.

Charging systems have therefore been developed in which the charging devices are integrated into the curbstone or curb. This has the advantage that no charging stations block the sidewalks and thus disturb the visual impression. No additional space is much rather required with only existing infrastructure being used. A high degree of flexibility and retrofitting options exist due to the possibility of modularization. Damage to the charging infrastructure caused by accidents involving vehicles can also be avoided.

One embodiment of a curbstone configured with electronics for charging a vehicle is described in GB 2 592 186 A. This curbstone has a modular structure and comprises a base element into which a receiving container can be inserted. This container can be replaced and is not attached. Wireless telecommunication technologies and infrastructures, such as Wi-Fi, Bluetooth, or parking sensors, are integrated into this container. This curbstone also has a connection socket and optional battery packs.

Another curb module is described in DE 10 2020 205 561 A1 which comprises an accommodating space in a base element that is closed by a cover element. An inductive charging device, a status display that is visible from the outside, a receiving and transmitting unit, a buffer memory, and a control unit are arranged in the accommodating space.

The problem with these curb modules is, however, that the electronic components generate a large amount of heat, in particular when the vehicle is charging, which causes the interior to heat up. This increases the thermal load on the electronic components, which can cause damage to the electronic components due to overheating or, if temperature monitoring is present, at least delays the charging process, in which case the amount of energy transferred is reduced to protect the electronic components.

### SUMMARY

An aspect of the present invention is to provide a curbstone, paving stone or curbstone charging device for charging an energy accumulator of an electrically driven vehicle with which the greatest possible amount of heat can be dissipated in order to prevent a thermal overloading of the electronic components.

In an embodiment, the present invention provides a charging device for a curbstone, a paving stone, or a curbstone for charging an energy accumulator of an electrically driven vehicle. The charging device includes a main body, a protective cover, an interface unit, a power supply unit and at least one heat-generating electronic component. The main body comprises an accommodating space which is arranged on an inside of the main body, and an outer wall which comprises an inner wall surface and an outer wall surface. The inner wall surface is arranged to face away from the outer wall surface. The protection cover is configured to close the accommodating space. The power supply cable is arranged to project into the accommodating space in the main body. The at least one heat-generating electronic component is arranged in the accommodating space of the main body and connects the interface unit to the power supply cable. The at least one heat-generating electronic component either directly abuts against the inner wall surface of the outer wall of the main body in a heat-conducting manner, or at least one heat-conducting body is arranged to extend at least from the at least one heat-generating electronic component to the inner wall surface of the outer wall of the main body. The outer wall surface of the outer wall of the main body facing away from the inner wall surface rests against surrounding soil or against a foundation.

### BRIEF DESCRIPTION OF THE DRAWINGS

The present invention is described in greater detail below on the basis of embodiments and of the drawings in which:

FIG. 1 shows a schematic top view of a street with a curbstone charging device as defined in the present invention defining the boundary of the street;

FIG. 2 shows a perspective side view of a curbstone, a paving stone or a curbstone charging device according to the present invention with an open side cover;

FIG. 3 shows a schematic cross-sectional view of a curbstone, a paving stone or a curbstone charging device according to the present invention in a first embodiment;

FIG. 4 shows a schematized cross-sectional view of a curbstone, a paving stone or a curbstone charging device according to the present invention in a second embodiment;

FIG. 5 shows a schematized cross-sectional view of a curbstone, a paving stone or a curbstone charging device according to the present invention in a third embodiment;

FIG. 6 shows a schematized cross-sectional view of a curbstone, a paving stone or a curbstone charging device according to the present invention in a fourth embodiment; and

FIG. 7 shows a schematized cross-sectional view of a curbstone, a paving stone or a curbstone charging device according to the present invention in a fifth embodiment.

### DETAILED DESCRIPTION

A curbstone, a paving stone or a curbstone charging device according to the present invention for charging an energy accumulator of an electrically driven vehicle comprises a main body which is made of a concrete, natural stone, plastic or composite material, for example, by casting. “Concrete” is, of course, also to be understood as ultra-high performance concrete (UHPC), fiber-reinforced concrete or polymer concrete in which a plastic is used as a binder instead of cement. The main body can also be made of metal or at least comprise a metal wall or a metal container which is attached to the concrete or plastic of the rest of the main body. An accommodating space is configured inside the main body which is defined by the main body on several sides. The main body in particular comprises a bottom wall and three or four side walls. The accommodating space is closed by a protection cover which is placed, for example, on the upwardly pointing ends of the four side walls. The cover can, however, also define one or more side walls of the accommodating space. The protection cover thus defines the space and can absorb the impact of vehicles. The curbstone, the curbstone or the paving stone charging device also comprises an interface unit which, for example, is mechanically connected at least indirectly to the protection cover or to the main body and can be configured as a charging socket or an inductive pad. This mechanical connection can be either made directly or via lifting or swiveling mechanisms or via additional parts. An energy supply cable projects into the accommodating space of the main body and is connected to the interface unit via electronic components of a charging unit, which can be attached, for example, to the protection cover, but which can also be attached to the main body. These components of a charging unit can define a completely autonomous charging unit which only require a power connection and which contain all electronic components, as well as being available individually and serving in some manner to control or protect the interface unit and the charging process. Individual electronic components of the charging unit, such as an energy meter, a charging controller, a protective contactor or a transmitter/receiver unit for authentication, can accordingly also be arranged in the accommodating space. Components of the charging unit are thus understood to mean individual components or several components that can be used to charge the energy accumulator of the electric or hybrid vehicle. Some of these components are heat-generating electronic components, such as a protective device, a power supply or a charging controller. At least one of these heat-generating electronic components is arranged in the accommodating space of the main body and connects the interface unit to the power supply cable at least indirectly.

According to the present invention, at least one of the heat-generating electronic components is either in direct thermal contact with an inner wall surface of an outer wall of the main body, or one or more heat-conducting bodies extend at least from the heat-generating electronic component to the inner wall surface of the outer wall of the main body, wherein an outer wall surface of the outer wall facing away from the inner wall surface is in contact with the surrounding ground or foundation. The heat-conducting bodies serve to improve heat conduction to this inner wall surface. These can be either one or several bodies, which comprise at least one solid component with a heat conduction that is at least above that of the housing, or a wall surface of the electronic component to be connected. Contact is made over a particularly large area in order to create a large heat contact surface, which also improves heat conduction. An outer wall surface of the outer wall facing away from the inner wall surface rests against the surrounding soil. This surrounding soil, which can also be defined by a concrete foundation or similar, comprises a lower temperature than the surrounding air, in particular at critical external air temperatures, so that the surrounding soil can serve as a heat sink. The heat-generating electronic components are accordingly in direct or indirect contact with the bottom or the rear wall of the main body.

The heat generated by the electronic components is thereby either directly or indirectly dissipated into the ground. This significantly reduces the thermal load on the electronic components in the accommodating space, which can significantly stabilize the charging power since the charging times can be shortened with reduced energy transfer. The lifespan of the electronic components of the charging unit is also increased so that the maintenance intervals can also be extended.

All heat-generating electronic components can, for example, be either in direct contact with the inner wall surface of the outer wall of the main body, or one or more heat-conducting bodies can, for example, extend at least from the heat-generating electronic components to the inner wall surface of the outer wall of the main body, wherein outer wall surfaces of the outer walls facing away from the inner wall surfaces respectively rest against the surrounding soil. The heat of all heat-generating electronic components can accordingly be dissipated to the soil thus increasing their lifespan and accelerating the charging process since larger amounts of energy can be transferred per unit of time.

The at least one heat-generating electronic component can, for example, also be arranged in an electronics box and either directly contacts a wall defining the electronics box in a heat-conducting manner, or the heat-conducting body extends at least from the heat-generating electronic component to the wall defining the electronics box, which either directly contacts an inner wall or an additional heat-conducting body which extends at least from the wall defining the electronics box to the inner wall surface of the outer wall of the main body, wherein an outer wall surface of the outer wall facing away from the inner wall surface rests against the surrounding soil. Such an electronics box can be configured as an encapsulation, whereby the electronic components are reliably protected from the ingress of water and dirt, and can, for example, be attached to the protection cover or configured as a single piece therewith. The installation and replacement of the entire electronics is also significantly simplified thereby.

In an embodiment of the present invention, the heat-generating electronic component can, for example, be attached to the wall defining the electronics box or to the outer wall of the main body and is there in flat contact. As a result of this flat contact, a large area for heat transfer to the wall of the electronics box or of the accommodating space is generated, whereby the heat conduction to the outside is also improved.

It can, for example, be the case that a heat-conducting paste or pad is arranged as a heat-conducting body between the heat-generating electronic component and the wall defining the electronics box or the outer wall of the main body. These heat-conducting pastes and heat-conducting pads adapt to the adjacent surfaces so that air acting as an insulator is completely removed between the electronic component and the opposite wall thus significantly improving heat conduction to the outside. Conventional heat-conducting pads or heat-conducting pastes comprise a heat conductivity of about 1 to 16 W/m·K.

A flexible or solid body can, for example, also be arranged as a heat-conducting body between the heat-generating electronic component and the wall defining the electronics box or the outer wall of the main body, the thermal conductivity of which is higher than 12 W/m·K. This can, for example, be a block of aluminum or an aluminum alloy. This makes it possible to arrange the electronic component in the electronics box or the accommodating space as desired while still providing good heat conduction to the outside into the soil.

In an alternative embodiment of the present invention, a Peltier element can, for example, be arranged as a heat-conducting body between the heat-generating electronic component and the wall defining the electronics box or the outer wall of the main body, the cold side of which rests against the heat-generating electronic component and the warm side of which rests against the wall defining the electronics box or the outer wall of the main body. Since the curbstone, the paving stone or the curbstone charging device includes a power connection in any case, an active cooling of the electronic component can also be carried out by energizing the Peltier element. This makes an active control of the cooling possible.

In another alternative embodiment of the present invention, at least one heat pipe can, for example, be arranged as a heat-conducting body between the heat-generating electronic component and the wall defining the electronics box or the outer wall of the main body, which heat pipe extends from the heat-generating electronic component to the wall defining the electronics box or to the outer wall of the main body. Heat can thus also be reliably dissipated by the liquid present in the heat pipe.

When using an electronics box, the wall defining the electronics box can, for example, be in direct contact with the outer wall of the main body, thus providing a direct heat transfer from the wall of the electronics box to the outer wall of the main body of the charging device.

In order to additionally improve the heat transfer between the electronics box and the main body and thus the soil and to avoid insulation by air, a heat-conducting body in the form of a heat-conducting paste, a heat-conducting pad, a graphite foil, or a spring plate extends between the wall defining the electronics box and the outer wall of the main body.

A Peltier element can alternatively be arranged as a heat-conducting body between the electronics box and the outer wall of the main body, with its cold side resting against the electronics box and with its warm side resting against the outer wall of the main body. This allows large amounts of heat to be dissipated from the electronics box and, if desired, a temperature control to be carried out.

Ribs can also be configured as heat-conducting bodies between the wall defining the electronics box and the outer wall, or a metal foam can be arranged between the wall defining the electronics box and the outer wall of the main body. This increases the surface area of the electronics box available for heat transfer and thus also leads to improved heat dissipation.

The use of a heat pipe as a heat-conducting body works particularly well if the at least one heat pipe extends from the wall defining the electronics box through the outer wall of the main body into the soil. This results in higher heat gradients between the ends of the heat pipe, which lead to a higher heat flow in the heat pipe and thus to an improved heat dissipation into the soil. A heat pipe arranged in this way can also be used for heating in winter when the outside air temperature is below that of the soil.

Ribs or a metal foam can, for example, be configured at the housing of the heat-generating electronic component via which the heat dissipation from the electronic component itself is improved.

In an embodiment of the present invention, the electronics box can, for example, be made of a material whose thermal conductivity is higher than 12 W/m·K and which serves as a heat-conducting body so that heat conduction from the electronics box is improved and does not have an insulating effect.

This provides a curbstone, a paving stone or a curbstone charging device for charging an energy accumulator of an electrically driven vehicle which is completely autonomous and which only requires a connection to a power supply cable that is particularly easy to connect. This charging device is insensitive to thermal influences since the heat of the electronic components is reliably dissipated into the soil, whereby the lifespan of the electronic components is extended and the charging process can be carried out with larger amounts of energy since a throttling of the transmitted energy quantities due to overheating can be reduced. Shorter charging times can accordingly be achieved.

A non-limiting embodiment of a curbstone, a paving stone or a curbstone charging device for charging an energy accumulator of an electrically driven vehicle according to the present invention is described below with reference to the drawings.

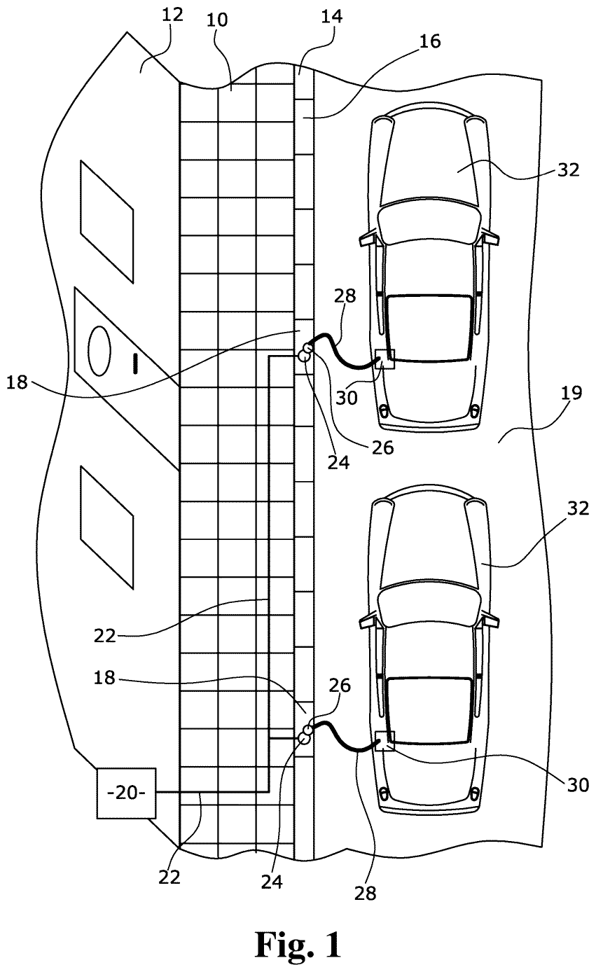

FIG. 1 shows a walkway 10, which is defined on one side by a house wall 12 and on the other side by a curbstone edge 14, which is formed by several stone elements 16 and curbstone charging devices 18 according to the present invention and configures a boundary to the street 19. An energy source 20 in the form of a power connection connected to the electricity grid is arranged on the side of the walkway 10 facing away from the curbstone edge 14. The energy source 20 is connected to the curbstone charging devices 18 via underground power supply cables 22. Interface units 24 in the form of charging sockets are arranged on the curbstone charging devices 18, into which a plug 26 is inserted, which is connected via a cable 28 to an energy accumulator 30, in particular to a battery of an electrically driven vehicle 32, so that this energy accumulator 30 can be charged via the energy source 20.

The curbstone, paving stone or curbstone charging device 18 comprises a main body 34 made of concrete or plastic, which may contain reinforcements, as well as an accommodating space 36 provided in the main body 34, which is a substantially hollow cuboid and which is closed by a protection cover 38 on a side open to the surface of the walkway 10.

The protection cover 38, which is in particular made of steel, is attached to the main body 34 and/or to an accommodating container 40 arranged inside, which can define a part of the main body 34 and closes the upwardly facing, open side of the accommodating space 36, in particular with the interposition of a seal (which is not shown). The protection cover 38 rests on a top side of the main body 34 and extends beyond the ends of the accommodating space 36, as viewed in the direction of its longitudinal extent.

The protection cover 38 comprises a rounded crash barrier 42 which covers an edge between the upper side of the main body 34 and a side surface of the main body 34 facing the street. The protection cover 38 can be attached by screws 44. The protection cover 38 defines the upper end of the accommodating space 36 formed inside the main body 34.

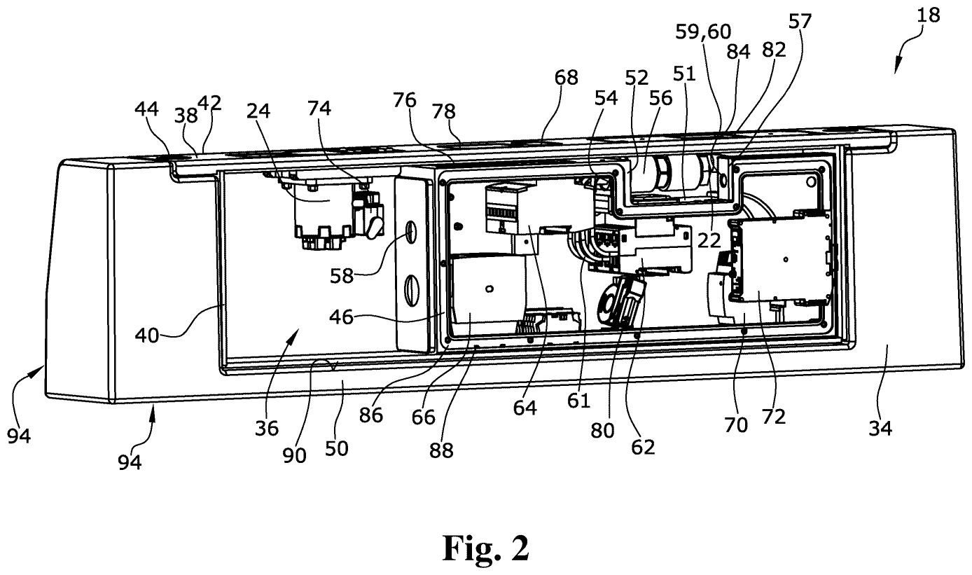

As can be seen in FIG. 2, an additional dust- and liquid-tight electronics box 46 is arranged in the interior of the accommodating space 36, in which dust- and liquid-tight electronics box 46 heat-generating electronic components 48 are arranged and which can be attached to the protection cover 38 or can be configured in one piece therewith.

The dust-tight and liquid-tight electronics box 46 is designed to be somewhat smaller on a first side so that a first free space is generated between the accommodating space 36 and the dust-tight and liquid-tight electronics box 46 which faces the street 19, but which could also face the walkway 10, and through which the power supply cable 22 is passed from below. This cable is drawn from below through an invisible hole in a bottom of the main body 34 and through an outer wall 50 that defines the main body 34 at the bottom into the accommodating container 40 and is guided upwards and to the side into a second free space between the protection cover 38 and an outer wall 51 that defines the dust- and liquid-tight electronics box 46 in the direction of the protection cover 38, which in this section accordingly comprises a distance to the protection cover 38 and in the adjoining section is arranged directly opposite the protection cover 38 and attached thereto by screws.

A first opening 54 is configured on a wall 52 of the dust- and liquid-tight electronics box 46, which vertically defines the second free space, through which first opening 54 a connection contact 56 extends to which the power supply cable 22 is connected and which can be configured as a terminal or plug-in connector socket. The connection contact 56 is sealed in the first opening 54 so that no liquid, dust or other impurities can penetrate. The power supply for the electronic components 48 inside the dust- and liquid-tight electronics box 46, and thus also for the interface unit 24, which, as shown in FIG. 2, is arranged outside of the dust- and liquid-tight electronics box 46, is provided via this connection contact 56 so that a second opening 58 is used for the sealed feed-through of an electrical line to the interface unit 24.

At the vertical wall 57 opposite the wall 52 defining the vertical boundary, a third opening 59 is configured at the dust- and liquid-tight electronics box 46 in which a pressure equalization membrane 60 is placed via which air can enter and leave the dust- and liquid-tight electronics box 46, whereby a pressure difference between the interior and the exterior of the dust- and liquid-tight electronics box 46 can be equalized so that no liquid can enter due to existing pressure differences.

Power cables 61 continue from the connection contact 56 to a combined fault current and circuit breaker 62, which can also be configured as individual switches. This is arranged directly below the outer wall 50 and can be operated or reset from the first free space.

This fault current and circuit breaker 62 is connected to an energy meter 64, which is connected to the interface unit 24 via further (not shown) power cables with a protective contactor 66 connected in between so that the interface unit is indirectly connected to the power supply cable 22.

The energy meter 64 is arranged below an inspection window 68 in the protection cover 38 through which a display unit of the energy meter 64 can be read.

A power supply 70 is supplied with power via a line with a line fuse. This power supply 70 is arranged at the bottom of the dust- and liquid-tight electronics box 46 and converts the high-voltage applied into a low-voltage, in particular into a 12V voltage. The power supply 70 supplies power to a charging control 72 which is arranged directly next to the power supply 70 and which is used to monitor and control the charging process. The protective contactor 66, which is also arranged at the bottom of the dust- and liquid-tight electronics box 46, is switched via the charging control 72. Before the protective contactor 66 can be switched via the charging control 72, a locking actuator 74 of the interface unit 24 must be switched in this embodiment having a charging socket, and before that, the user must be authenticated via an RFID board 76, which is arranged directly below a display window 78 in the protection cover 38, so that visualization of the authentication is possible via LEDs of the RFID board 76.

A fault current sensor 80 is connected between the protective contactor 66 and the energy meter 64 which detects DC currents between the protective contactor 66 and the energy meter 64 that may be triggered by a vehicle-side charger and prevents AC fault currents from being detected sufficiently reliably by the fault current and circuit breaker 62, which can lead to personal injury. The power supply in this case is accordingly interrupted via the charging control 72.

A transmitter/receiver unit 84, which may be configured as a radio antenna, is furthermore arranged in a plastic part 82 of the protection cover 38, the connection cable of which leads to the charging control 72 in the dust- and liquid-tight electronics box 46 via a further sealed opening.

If a vehicle is to be charged, the user is first identified via the RFID board 76 and the transmitter/receiver unit 84. After the plug 26 is inserted, the locking actuator 74 is switched before the charging process is started, thus preventing the plug 26 from being pulled out unexpectedly during the charging process, as this would place the user in danger. It is only after the locking actuator 74 has been switched that the protective contactor 66 is switched via the charging control 72 so that the charging process can begin.

The energy meter 64 comprises a data interface which is provided as a Mod-Bus for the charging control 72 so that the data of the energy meter 64 are transmitted to the charging control 72 during the charging process and are stopped when the charging process is completed, either due to an external command or the detection of a full charge of the energy accumulator 30.

In this embodiment, the heat-generating electronic components 48, in particular the charging control 72, the power supply 70, the protective contactor 66 and the fault current and circuit breaker 62, are in a large-area contact with a wall 86 that faces the walkway 10, defines the electronics box 46, and is largely cut away in FIG. 2.

The protective contactor 66 and the power supply 70 are also in contact with the wall 88 that defines the electronics box 46 at the bottom. The wall 86 facing the walkway 10 and defining the electronics box 46 and the wall 88 of the electronics box 46 forming the bottom and defining the electronics box 46 lie against an inner wall surface 90 of the rear lateral outer wall 50 facing the surrounding soil 92 or of the main body 34 so that the heat can be dissipated via the walls 86, 88 of the electronics box 46 and the outer walls 50 of the main body 34 to the soil 92 which is located behind and below via an outer wall surface 94 of the outer wall 50. To provide good heat conduction from the electronics box 46 to the outer wall 50 of the main body 34, the electronics box 46 can, for example, made of aluminum and comprise a heat conductivity of more than 200 W/m·K. The configuration of the electronics box 46 means that it can be used as a heat-conducting body 96 from the heat-generating electronic components 48 to the outer walls 50 of the main body 34, which are located opposite the soil 92, from where the heat can in turn be dissipated into the soil 92.

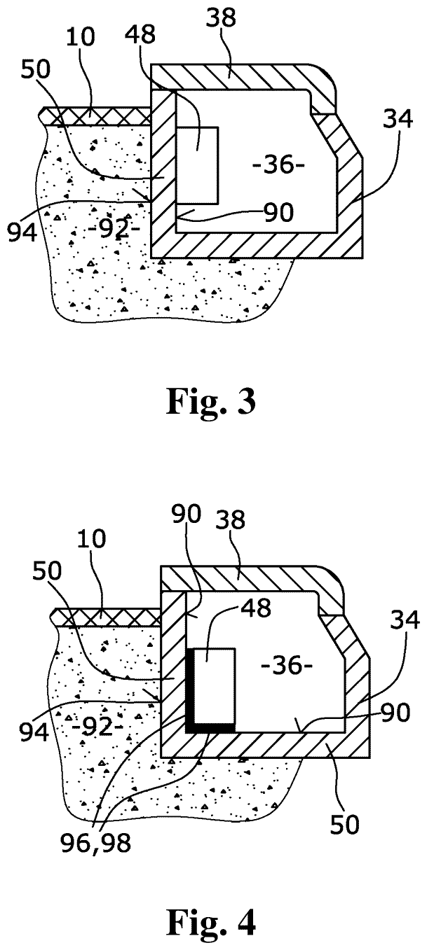

FIGS. 3 to 7 schematically show further alternatives for dissipating heat from the heat-generating electronic components 48 to the soil 92.

In FIG. 3, the heat-generating component 48 shown is in direct contact with the inner wall surface 90 of the outer wall 50 of the main body 34. An additional electronics box 46 is accordingly not provided in this embodiment.

In FIG. 4, a heat-conducting paste or pad 98 is arranged between the heat-generating electronic components 48 and the inner wall surfaces 90 of the side and bottom outer walls 50 of the main body 34 facing the soil 92 as a heat-conducting body 96. This heat-conducting paste or pad substitutes small, insulating air pockets between the inner wall surface 90 and the electronic component 48, thus further improving heat dissipation.

Another alternative embodiment is shown in FIG. 5. In order to improve the heat dissipation from the electronic component 48, ribs 100 are configured at a housing 99 of the electronic component 48 for enlarging the available heat-conducting surface, which ribs 100 project into the accommodating space 36, and a Peltier element 102 is arranged between the electronic component 48 and the inner wall surface 90 of the outer wall 50 of the main body 34 as a heat-conducting body 96. Such a Peltier element 102 is an electro-thermal converter which, based on the Peltier effect, generates a temperature difference when current flows therethrough. The Peltier element is here accordingly connected to the power supply of the curbstone charging device 18 or to the charging control 72. A cold side 104 of the Peltier element 102, due to the current flow, is in contact with the heat-generating electronic component 48, while a warm side 106 is in contact with the inner wall surface 90 of the outer wall 50. The electronic component 48 can accordingly be actively cooled in response to the current flow and the heat generated on the other side can be dissipated to the soil 92. By reversing the voltage, it would also be possible with such a Peltier element 102 to preheat the electronic components 48, for example, at very low outside temperatures in winter.

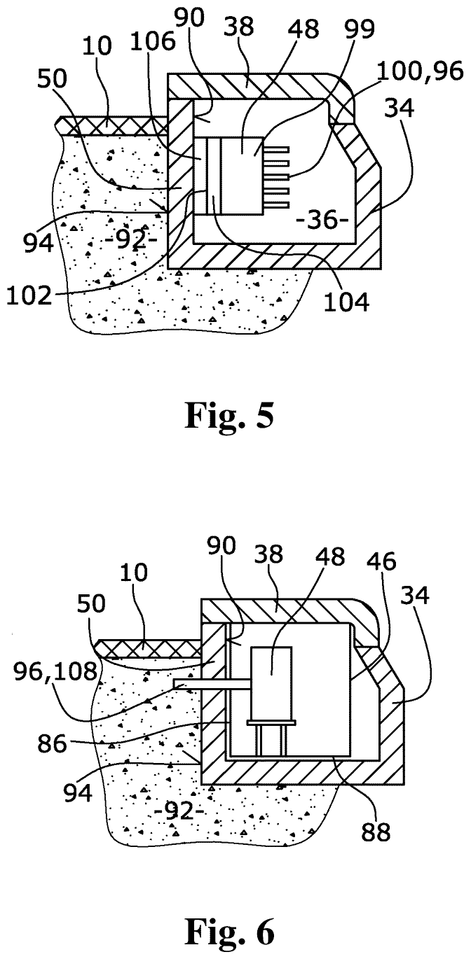

In the alternative embodiment according to FIG. 6, the heat-generating electronic component 48 is located inside the accommodating space 36. A heat pipe 108 firstly extends from the heat-generating electronic component 48 to the wall 88 defining the electronics box 46 and secondly further through the wall 88 to the inner wall surface 90 and through the outer wall 50 of the main body 34 into the soil 92 and serves as a heat-conducting body 96. Due to the temperature gradients that occur between the soil 92 at the first end of the heat pipe 108 and the heat-generating electronic component 48 at the other end of the heat pipe 108, an energy flow is generated through the liquid in the heat pipe 108, whereby the heat is dissipated outwards into the soil 92.

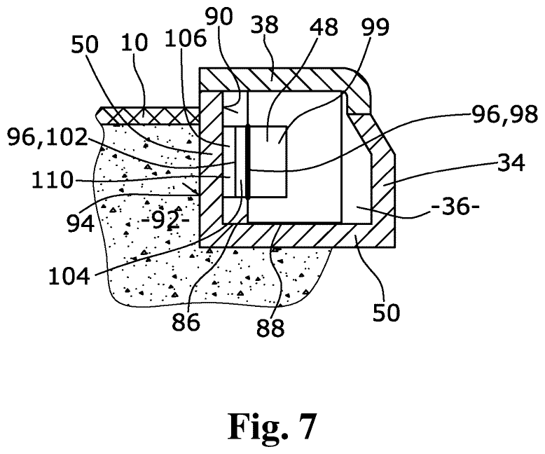

In a further alternative embodiment according to FIG. 7, the electronic component is connected to the wall 88 of the electronics box 46, with the interposition of a heat-conducting paste 98 serving as a first heat-conducting body 96, while a Peltier element 102 serving as an additional heat-conducting body 110 is arranged between the wall 88 and the inner wall surface 90 or the outer wall 50 of the main body 34, the cold side 104 of the Peltier element 102 resting against the wall 88 when current flows, and the warm side 106 of the Peltier element 102 resting against the inner wall surface 90 of the outer wall 50, so that in this case a heat-conducting connection is also made for dissipating the heat via the heat-conducting paste 98 to the wall 88 of the electronics box 46, and heat is drawn off from the electronics box 46 by the Peltier element 102 in the direction of the outer wall 50.

All these possible embodiments provide an improved heat flow from the electronic components in the direction of the soil, which results in a longer service life for the electronic components and opens up the possibility of accelerating the charging process, since a reduction in the energy flow to the vehicle to prevent thermal overloads in the charging device during the charging process must be carried out much less frequently.

It should be clear that the electronics can be adapted to the respective conditions, in particular the legal conditions of the countries, and that any number of electronic components can be coupled to the outer wall in a thermally conductive manner in any way desired according to the present invention. Any combination thereof are also possible in addition to the embodiments described.

The present invention is not limited to embodiments described herein; reference should be had to the appended claims.

### LIST OF REFERENCE NUMERALS

10 Walkway
12 House wall
14 Curbstone edge
16 Stone element
18 Curbstone charging device
19 Street
20 Energy source
22 Power supply cable
24 Interface unit
26 Plug
28 Cable
30 Energy accumulator
32 Electrically driven vehicle
34 Main body
36 Accommodating space
38 Protection cover
40 Accommodating container
42 Crash barrier
44 Screw
46 Dust- and liquid-tight electronics box/Electronics box
48 Electronic component
50 Outer wall
51 Outer wall
52 Wall
54 First opening
56 Connection contact
57 Vertical wall
58 Second opening
59 Third opening
60 Pressure equalization membrane
61 Power cables
62 Fault current and circuit breaker
64 Energy meter
66 Protective contactor
68 Inspection window
70 Power supply
72 Charging control
74 Locking actuator
76 RFID board
78 Display window
80 Fault current sensor
82 Plastic part
84 Transmitter/receiver unit
86 Wall (facing walkway 10)
88 Wall (of electronics box 46)
90 Inner wall surface
92 Soil
94 Outer wall surface
96 Heat-conducting body
98 Heat-conducting paste or pad
99 Housing
100 Rib
102 Peltier element
104 Cold side
106 Warm side
108 Heat pipe
110 Additional heat-conducting body

What is claimed is:

1-15. (canceled)

16. A charging device for a curbstone, a paving stone or a curbstone for charging an energy accumulator of an electrically driven vehicle, the charging device comprising:
a main body comprising an accommodating space which is arranged on an inside of the main body, and an outer wall which comprises an inner wall surface and an outer wall surface, the inner wall surface being arranged to face away from the outer wall surface;
a protection cover which is configured to close the accommodating space;
an interface unit;
a power supply cable which is arranged to project into the accommodating space in the main body; and
at least one heat-generating electronic component which is arranged in the accommodating space of the main body and which connects the interface unit to the power supply cable;
wherein,
the at least one heat-generating electronic component either directly abuts against the inner wall surface of the outer wall of the main body in a heat-conducting manner, or at least one heat-conducting body is arranged to extend at least from the at least one heat-generating electronic component to the inner wall surface of the outer wall of the main body, and
the outer wall surface of the outer wall of the main body facing away from the inner wall surface rests against surrounding soil or against a foundation.

17. The charging device as recited in claim 16, wherein,
each of the at least one heat-generating electronic component either directly contact the inner wall surface of the outer wall of the main body in a heat-conducting manner, or the at least one heat-conducting body extend at least from the at least one heat-generating electronic component to the inner wall surface of the outer wall of the main body, and
the outer wall surface of the outer wall facing away from the inner wall surface rests against the surrounding soil.

18. The charging device as recited in claim 16, further comprising:
an electronics box comprising at least one wall,
wherein,
the at least one heat-generating electronic component is arranged in the electronics box so as to either rest in a heat-conducting manner directly against the at least one wall of the electronics box, or the at least one heat-conducting body extends at least from the at least one heat-generating electronic component to the at least one wall of the electronics box, and
the at least one wall of the electronics box either directly abuts against the inner wall surface of the outer wall of the main body, or the at least one heat-conducting body or an additional heat-conducting body extends at least from the at least one wall of the electronics box to the inner wall surface of the outer wall of the main body.

19. The charging device as recited in claim 18, wherein the at least one heat-generating electronic component is attached to the at least one wall of the electronics box or to the outer wall of the main body via a full-surface contact.

20. The charging device for as recited in claim 18, wherein,
the at least one heat-conducting body and/or the additional heat-conducting body is provided as a heat-conducting paste or pad, and
the heat-conducting paste or pad is arranged as the at least one heat-conducting body and/or as the additional heat-conducting body between the at least one heat-generating electronic component and the at least one wall of the electronics box or between the at least one heat-generating electronic component and the outer wall of the main body.

21. The charging device as recited in claim 18, wherein,
the at least one heat-conducting body and/or the additional heat-conducting body is provided as a flexible body or as a solid body,
the flexible body or the solid body is arranged as the at least one heat-conducting body and/or as the additional heat-conducting body between the at least one heat-generating electronic component and the at least one wall of the electronics box or between the at least one heat-generating electronic component and the outer wall of the main body, and
a thermal conductivity of the flexible body or the solid body is higher than 12 W/m·K.

22. The charging device as recited in claim 18, wherein,
the at least one heat-conducting body and/or the additional heat-conducting body is provided as a Peltier element,
the Peltier element has a cold side and a warm side,
the Peltier element is arranged as the at least one heat-conducting body and/or as the additional heat-conducting body between the at least one heat-generating electronic component and the at least one wall of the electronics box or between the at least one heat-generating electronic component and the outer wall of the main body,
the cold side off the Peltier element rests against the at least one heat-generating electronic component, and
the warm side of the Peltier element rests against the at least one wall of the electronics box or against the outer wall of the main body.

23. The charging device as recited in claim 18, wherein,
the at least one heat-conducting body and/or the additional heat-conducting body is provided as at least one heat pipe,
the at least one heat pipe is arranged between the at least one heat-generating electronic component and the at least one wall of the electronics box or between the at least one heat-generating electronic component and the outer wall of the main body, and
the at least one heat pipe is arranged to extend from the at least one heat-generating electronic component to the at least one wall of the electronics box and/or from the at least one heat-generating electronic component to the outer wall of the main body.

24. The charging device as recited in claim 18, wherein the at least one wall of the electronics box is in a direct contact with the outer wall of the main body.

25. The charging device as recited in claim 18, wherein,
the at least one heat-conducting body and/or the additional heat-conducting body is provided as a heat-conducting paste, a heat-conducting pad, a graphite foil, or as a spring plate, and
the heat-conducting paste, the heat-conducting pad, the graphite foil, or the spring plate is arranged between the at least one wall of the electronics box and the outer wall of the main body.

26. The charging device as recited in claim 18, wherein,
the at least one heat-conducting body and/or the additional heat-conducting body is provided as a Peltier element,
the Peltier element has a cold side and a warm side, and
the Peltier element is arranged between the electronics box and the outer wall of the main body so the cold side of the Peltier element bears against the electronics box and the warm side of the Peltier element bears against the outer wall of the main body.

27. The charging device as recited in claim 18, wherein,
the at least one heat-conducting body and/or the additional heat-conducting body is provided as ribs which are arranged to face the outer wall, each one of the ribs comprising an end which is in a direct contact with the outer wall, or
the at least one heat-conducting body and/or the additional heat-conducting body is provided as a metal foam which is arranged between the at least one wall of the electronics box and the outer wall of the main body.

28. The charging device as recited in claim 27, wherein,
the at least one heat-generating electronic component comprises a housing, and
the ribs or the metal foam are arranged at the housing of the heat-generating electronic component.

29. The charging device as recited in claim 18, wherein,
the at least one heat-conducting body and/or the additional heat-conducting body is provided as at least one heat pipe, and
the at least one heat pipe is arranged to extend from the at least one wall of the electronics box through the outer wall of the main body into the surrounding soil.

30. The charging device as recited in claim 18, wherein the electronics box is made of a material whose thermal conductivity is higher than 12 W/m·K and which serves as a heat-conducting body.
